(19) United States
(12) Patent Application Publication
(10) Pub. No.: US 2017/0023617 A1
(43) Pub. Date: Jan. 26, 2017

(54) SHAPING OF CONTACT STRUCTURES FOR SEMICONDUCTOR TEST, AND ASSOCIATED SYSTEMS AND METHODS

(71) Applicant: Translarity, Inc., Fremont, CA (US)

(72) Inventors: Jens Ruffler, Beaverton, OR (US); Douglas A. Preston, McMinnville, OR (US); Christopher T. Lane, Los Gatos, CA (US); Thomas Aitken, Walnut Creek, CA (US)

(73) Assignee: Translarity, Inc., Fremont, CA (US)

(21) Appl. No.: 15/178,747

(22) Filed: Jun. 10, 2016

Related U.S. Application Data
(60) Provisional application No. 62/230,604, filed on Jun. 10, 2015.
(60) Provisional application No. 62/230,606, filed on Jun. 10, 2015.
(60) Provisional application No. 62/230,609, filed on Jun. 10, 2015.
(60) Provisional application No. 62/254,605, filed on Nov. 12, 2015.
(60) Provisional application No. 62/255,231, filed on Nov. 13, 2015.
(60) Provisional application No. 62/276,000, filed on Jan. 7, 2016.

(51) Int. Cl. G01R 1/073; H01L 23/00; G01R 31/26; H01L 21/683

(52) U.S. Cl. CPC G01R 1/07378; H01L 21/6838; H01L 24/741; G01R 31/26; H01L 2224/749

(57) ABSTRACT

Systems and methods for testing semiconductor wafers using a wafer translator are disclosed herein. In one embodiment, an apparatus for adjusting a wafer translator for testing semiconductor dies includes the semiconductor wafer translator having a wafer translator substrate with a wafer-side configured to face the dies. A plurality of wafer-side contact structures is carried by the wafer-side of the wafer translator. The apparatus also includes a shaping wafer having a shaping wafer substrate, and a plurality of cavities in the shaping wafer substrate. The wafer-side contact structures are shaped by contacting surfaces of the cavities of the shaping wafer substrate.

### CROSS-REFERENCES TO RELATED APPLICATIONS

This application claims the benefit of U.S. Provisional Application Ser. No. 62/230,604, filed Jun. 10, 2015, U.S. Provisional Application No. 62/230,606, filed June 10, 2015, U.S. Provisional Application No. 62/230,609, filed Jun. 10, 2015, U.S. Provisional Application No. 62/254,605, filed Nov. 12, 2015, U.S. Provisional Application No. 62/255,231, filed Nov. 13, 2015, and U.S. Provisional Application No. 62/276,000, filed Jan. 7, 2016, all of which are hereby incorporated by references in their entireties.

### FIELD OF THE INVENTION

The present invention relates generally to semiconductor equipment. More particularly, the present invention relates to methods and apparatus for the planarization and shaping of electrical contact structures.

### BACKGROUND

Integrated circuits are used in a wide variety of products. Integrated circuits have continuously decreased in price and increased in performance, becoming ubiquitous in modern electronic devices. These improvements in the performance/cost ratio are based, at least in part, on miniaturization, which enables more semiconductor dies to be produced from a wafer with each new generation of the integrated circuit manufacturing technology. Furthermore, the total number of the signal and power/ground contacts on a semiconductor die generally increases with new, more complex die designs.

Prior to shipping a semiconductor die to a customer, the performance of the integrated circuits is tested, either on a statistical sample basis or by testing each die. An electrical test of the semiconductor die typically includes powering the die through the power/ground contacts, transmitting signals to the input contacts of the die, and measuring the resulting signals at the output contacts of the die. Therefore, during the electrical test at least some contacts on the die must be electrically contacted to connect the die to sources of power and test signals.

Conventional test contactors include an array of contact pins attached to a substrate that can be a relatively stiff printed circuit board (PCB). In operation, the test contactor is pressed against a wafer such that the array of contact pins makes electrical contact with the corresponding array of die contacts (e.g., pads or solderballs) on the dies (i.e., devices under test or DUTs) of the wafer. Next, a wafer tester sends electrical test sequences (e.g., test vectors) through the test contactor to the input contacts of the dies of the wafer. In response to the test sequences, the integrated circuits of the tested die produce output signals that are routed through the test contactor back to the wafer tester for analysis and determination whether a particular die passes the test. Next, the test contactor is stepped onto another die or group of dies that are tested in parallel to continue testing till the entire wafer is tested.

In general, an increasing number of die contacts that are distributed over a decreasing area of the die results in smaller contacts spaced apart by smaller distances (e.g., a smaller pitch). Furthermore, a characteristic diameter of the contact pins of the test contactor generally scales with a characteristic dimension of the contact structures on the semiconductor die or the package. Therefore, as the contact structures on the die become smaller and/or have a smaller pitch, the contact pins of the test contactors become smaller, too. However, it is difficult to significantly reduce the diameter and pitch of the contact pins of the test contactor, e.g., because of the difficulties in machining and assembling such small parts, resulting in low yield and inconsistent performance from one test contactor to another. Additionally, the contact pins of the test contactor can be relatively easily damaged because of their small size. Furthermore, precise alignment between the test contactor and the wafer is difficult because of the relatively small size/pitch of the contact structures on the wafer.

Accordingly, there remains a need for cost effective test contactors that can scale down in size with the size and pitch of the contact structure on the die.

### BRIEF DESCRIPTION OF THE DRAWINGS

The aspects of the present disclosure can be better understood with reference to the following drawings. The components in the drawings are not necessarily to scale. Instead, emphasis is placed on clearly illustrating the principles of the present disclosure.

FIG. 1A is an exploded view of a portion of a test stack for testing semiconductor wafers in accordance with an embodiment of the presently disclosed technology.

FIG. 1B is a partially schematic, top view of a wafer translator configured in accordance with an embodiment of the presently disclosed technology.

FIG. 1C is a partially schematic, bottom view of a wafer translator configured in accordance with an embodiment of the presently disclosed technology.

FIG. 1D is a partial side view of a wafer translator in accordance with an embodiment of the presently disclosed technology.

FIGS. 2-4 are partial side views of the systems for shaping the wafer-side contact structures in accordance with the embodiments of the presently disclosed technology.

FIG. 5 is a partial side view of a system for shaping the wafer-side contact structures in accordance with an embodiment of the presently disclosed technology.

FIGS. 6A-6F are partial side views of the wafer-side contact structures in accordance with the embodiments of the presently disclosed technology.

FIGS. 7A and 7B are partially schematic views of a system for shaping the wafer-side contact structures in accordance with the embodiments of the presently disclosed technology.

### DETAILED DESCRIPTION

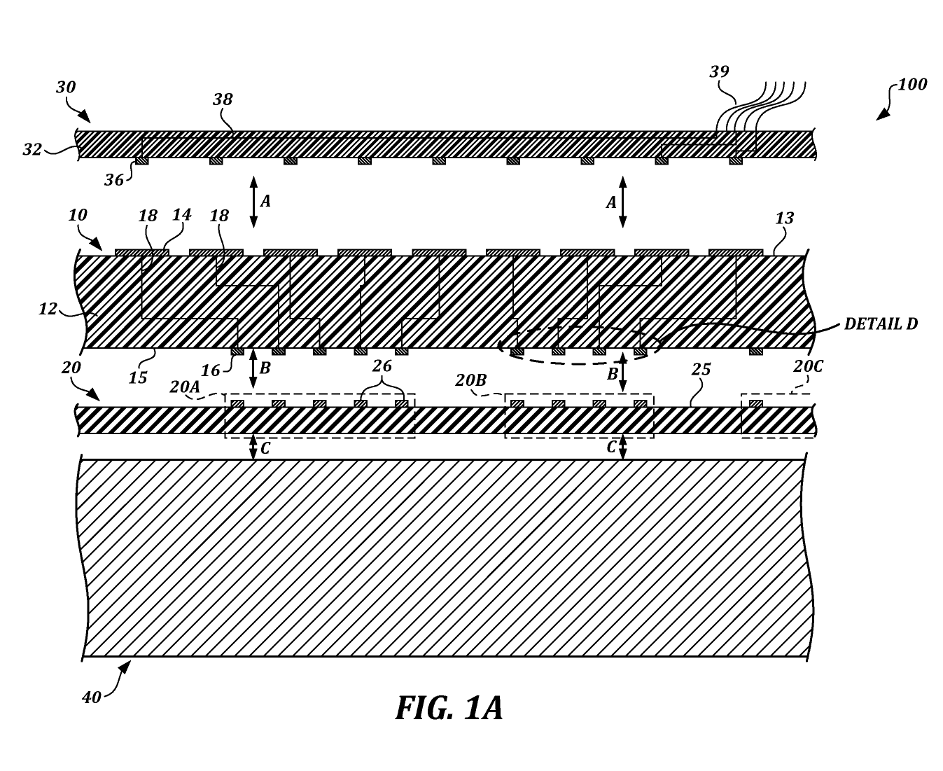

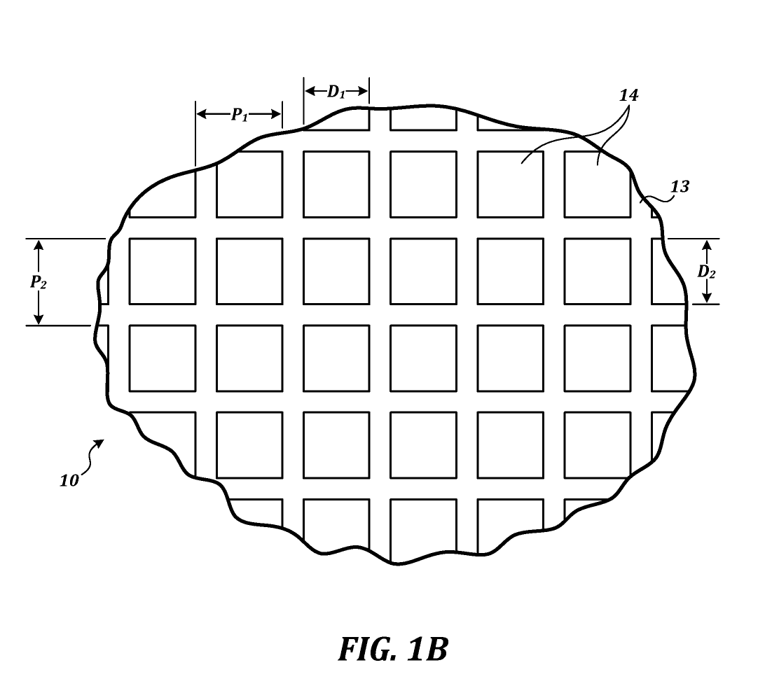

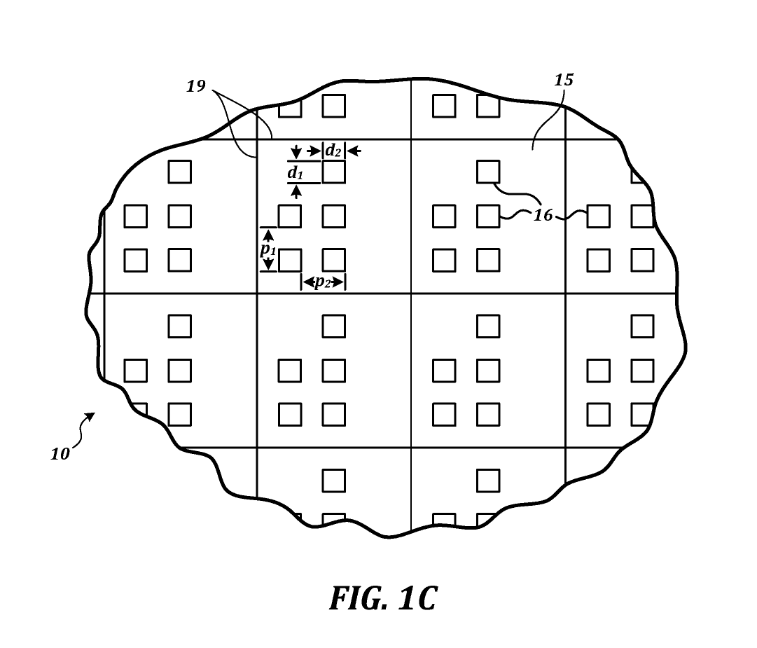

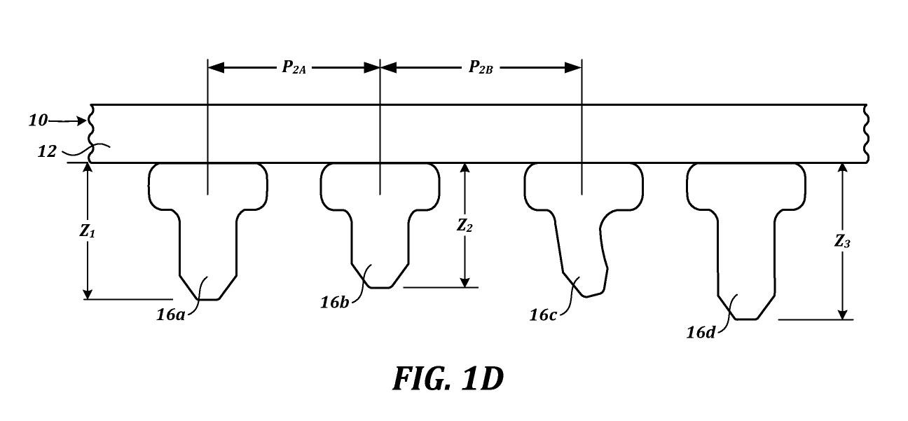

Specific details of several embodiments of representative wafer translators and associated methods for use and manufacture are described below. The wafer translators can be used for testing semiconductor dies on a wafer. The semiconductor dies may include, for example, memory devices, logic devices, light emitting diodes, micro-electro-mechanical-systems, and/or combinations of these devices. A person skilled in the relevant art will also understand that the technology may have additional embodiments, and that the technology may be practiced without several of the details of the embodiments described below with reference to FIGS. 1A-7B.

Briefly described, methods and devices for testing dies on the semiconductor wafers are disclosed. The semiconductor wafers can be produced in different diameters, e.g., 150 mm, 200 mm, 300 mm, 450 mm, etc. The disclosed methods and systems enable operators to test devices having pads, solderballs and/or other contact structures having small sizes and/or pitches. Solderballs, pads, and/or other suitable conductive elements on the dies are collectively referred to herein as “contact structures” or “contacts.” In many embodiments, the technology described in the context of one or more types of contact structures can also be applied to other contact structures.

In some embodiments, a wafer-side of the wafer translator carries the wafer-side contact structures having relatively small sizes and/or pitches (collectively, “scale”). The wafer-side contact structures of the wafer translator are electrically connected to corresponding inquiry-side contact structures having relatively larger sizes and/or pitches at the opposite, inquiry-side of the wafer translator. Therefore, once the wafer-side contact structures are properly aligned to contact the semiconductor wafers, the larger size/pitch of the opposing inquiry-side contact structures enable more robust contact (e.g., requiring less precision). The larger size/pitch of the inquiry-side contact structures may provide more reliable contact and be easier to align against the pins of the test contactor. In some embodiments, the inquiry-side contacts may have mm scale, while the wafer-side contacts have sub-mm or μm scale.

In some embodiments, the contact structures at the wafer-side of the wafer translator can be wirebonds or stud bumps. For example, the wirebonds can be attached to the wafer-side using wirebonding equipment, followed by cutting the wirebonds to a required height.

In at least some embodiments, contact between the wafer translator and the wafer is kept by a vacuum in a space between the wafer translator and the wafer. For example, a pressure differential between a lower pressure (e.g., sub-atmospheric pressure) in the space between the wafer translator and the wafer, and a higher outside pressure (e.g., atmospheric pressure) can generate a force over the inquiry-side of the wafer translator resulting in a sufficient electrical contact between the wafer-side contact structures and the corresponding die contacts of the wafer.

Many embodiments of the technology described below may take the form of computer- or controller-executable instructions, including routines executed by a programmable computer or controller. Those skilled in the art will appreciate that the technology can be practiced on computer/controller systems other than those shown and described below. The technology can be embodied in a special-purpose computer, controller, or data processor that is specifically programmed, configured, or constructed to perform one or more of the computer-executable instructions described below. Accordingly, the terms “computer” and “controller” as generally used herein refer to any data processor and can include Internet appliances and hand-held devices (including palm-top computers, wearable computers, cellular or mobile phones, multi-processor systems, processor-based or programmable consumer electronics, network computers, mini computers and the like). Information handled by these computers can be presented by any suitable display medium, including a CRT display or LCD.

The technology can also be practiced in distributed environments, where tasks or modules are performed by remote processing devices that are linked through a communications network. In a distributed computing environment, program modules or subroutines may be located in local and remote memory storage devices. Aspects of the technology described below may be stored or distributed on computer-readable media, including magnetic or optically readable or removable computer disks, as well as distributed electronically over networks. Data structures and transmissions of data particular to aspects of the technology are also encompassed within the scope of the embodiments of the technology.

FIG. 1A is an exploded view of a portion of a test stack 100 for testing semiconductor wafers in accordance with an embodiment of the presently disclosed technology. The test stack 100 can route signals and power from a tester (not shown) to a wafer or other substrate carrying one or more devices under test (DUTs), and transfer the output signals from the DUTs (e.g., semiconductor dies) back to the tester for analysis and determination about an individual DUT's performance (e.g., whether the DUT is suitable for packaging and shipment to the customer). The DUT can be a single semiconductor die or multiple semiconductor dies (e.g., when using a parallel test approach). The signals and power from the tester may be routed through a test contactor 30 to a wafer translator 10, and further to the semiconductor dies on the wafer 20.

In some embodiments, the signals and power can be routed from the tester to the test contactor 30 using cables 39. Conductive traces 38 carried by a test contactor substrate 32 can electrically connect the cables 39 to contacts 36 on the opposite side of the test contactor substrate 32. In operation, the test contactor 30 can contact an inquiry-side 13 of a wafer translator 10 as indicated by arrows A. In at least some embodiments, relatively large inquiry-side contact structures 14 can improve alignment with the corresponding contacts 36 of the test contactor 30. The contact structures 14 at the inquiry-side 13 are electrically connected with relatively small wafer-side contact structures 16 on a wafer-side 15 of the translator 10 through conductive traces 18 of a wafer translator substrate 12. The size and/or pitch of the wafer-side contact structures 16 are suitable for contacting the corresponding die contacts 26 of the wafer 20. Arrows B indicate a movement of the wafer translator 10 to make contact with an active side 25 of the wafer 20. As explained above, the signals and power from the tester can test the DUTs of the wafer 20, and the output signals from the tested DUTs can be routed back to the tester for analysis and a determination as to whether the DUTs are suitable for packaging and shipment to the customer.

The wafer 20 is supported by a wafer chuck 40. Arrows C indicate the direction of the wafer 20 mating with the wafer chuck 40. In operation, the wafer 20 can be held against the wafer chuck 40 using, e.g., vacuum V or mechanical clamping.

FIGS. 1B and 1C are partially schematic, top and bottom views, respectively, of a wafer translator configured in accordance with embodiments of the presently disclosed technology. FIG. 1B illustrates the inquiry-side 13 of the wafer translator 10. Distances between the adjacent inquiry-side contact structures 14 (e.g., pitch) are denoted P₁ in the horizontal direction and P₂ in the vertical direction. The illustrated inquiry-side contact structures 14 have a width D₁ and a height D₂. Depending upon the embodiment, the inquiry-side contact structures 14 may be squares, rectangles, circles or other shapes. Furthermore, the inquiry-side contact structures 14 can have a uniform pitch (e.g., P₁ and P₂ being equal across the wafer translator 10) or a non-uniform pitch.

FIG. 1C illustrates the wafer-side 15 of the wafer translator 10. In some embodiments, the pitch between the adjacent wafer-side contact structures 16 can be p₁ in the horizontal direction and p₂ in the vertical direction. The width and height of the wafer-side contact structures 16 (“characteristic dimensions”) are denoted as d₁ and d₂. In some embodiments, the wafer-side contact structures 16 can be pins that touch corresponding die contacts on the wafer 20 (FIG. 1A). In general, the size/pitch of the inquiry-side contact structures 14 is larger than the size/pitch of the wafer-side contact structures 16, therefore improving alignment and contact between the test contactor and the wafer translator. The individual dies of the wafer 20 are typically separated from each other by wafer streets 19.

FIG. 1D is a partial side view of a wafer translator in accordance with an embodiment of the presently disclosed technology. The wafer-side contact structures 16a-16d may be made by, for example, wirebonding or stud-bumping technology. In general, the wafer-side contact structures 16a-16d may have non-uniform size, shape and/or pitch because of, for example, the manufacturing errors or tolerances, transportation damage, usage wearout, etc. For example, the wafer-side contact structures 16a, 16b and 16c have heights Z₁, Z₂ and Z₃, respectively. Furthermore, the pitch between the wafer-side contact structures 16a and 16b is P_{2A} (e.g, a within-specification value) while the pitch between the wafer-side contact structures 16b and 16c is P_{2B}, (e.g., an outside-of-specification value) that is different from the pitch P_{2A}. Additionally, the wafer-side contact structure 16c may be bent out of shape or not be perpendicular to the wafer translator substrate 12. Other examples of the non-uniform and/or outside-of-specification wafer-side contact structures 16 are possible. In operation, for example when contacting the dies on the wafer, the foregoing non-uniformities or outside-of-specification errors of the size/pitch/shape of the wafer-side contact structures 16 may cause contacting issues (e.g., no contact at all, contact with a wrong pad, a marginal contact, etc.). In some embodiments, the wafer translator 10 can be cut into segments that correspond to a die on the wafer, and the segments can be used as a packaging substrate for die packaging. For example, the segments of the wafer translator 10 can be aligned against the singulated die of the wafer 20, and the wafer-side contact structures 16a-16d can form intermetallic bonds with the die contacts 26 on the singulated die 20A to form a packaged die. In some embodiments, the contact structures 16a-16d can be wirebonds or stud bumps.

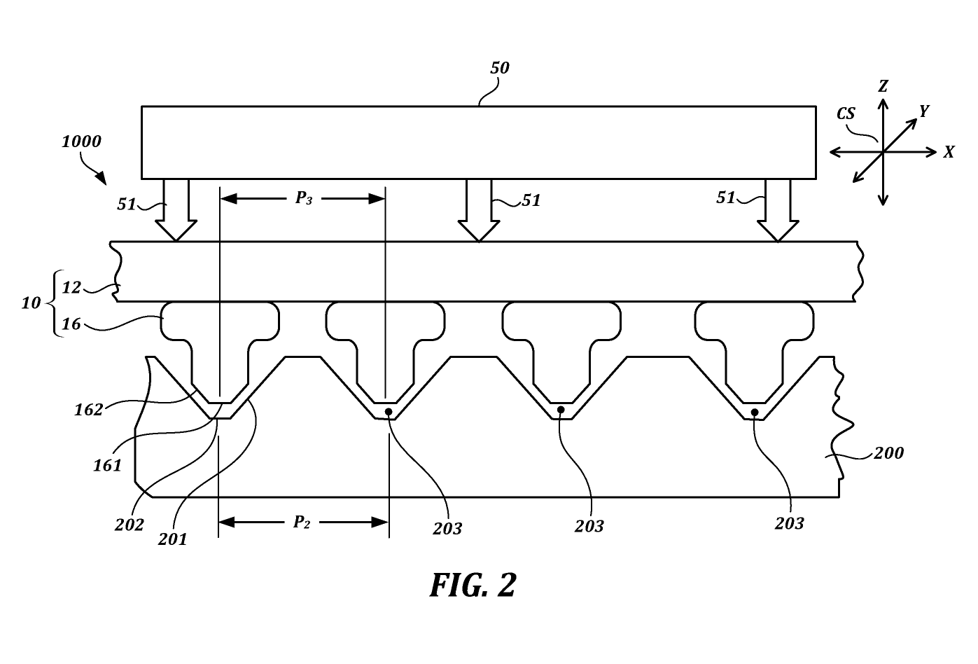

FIG. 2 is a partial side view of a system 1000 for shaping wafer-side contact structures 16 in accordance with an embodiment of the presently disclosed technology. In some embodiments, the system 1000 includes the wafer translator 10 and a shaping wafer 200. The wafer translator 10 may include the wafer-side contact structures 16 having different sizes, shapes and/or pitches, for example as explained with reference to FIG. 1D. In some embodiments, the shaping wafer 200 repeatedly contacts the wafer-side contact structures 16 to shape them. The wafer translator 10, or the shaping wafer 200, or both may be moved into contact in a Z-direction shown by a coordinate system CS by one or more actuators 50. The actuation may be provided by pressure driven actuators, electrical motors, or other actuators. In some embodiments, a force 51 between the wafer translator 10 and the shaping wafer 200 may be controlled by, for example, controlling the pressure of the pressure driven actuator 50. In some embodiments, the movements of the wafer translator 10 and/or the shaping wafer 200 may be limited to control the shaping of the wafer-side contact structures 16. For example, the wafer translator 10 may be moved into a position Z₁ for N₁ cycles, followed by forcing the wafer translator 10 into a position Z₂ for N₂ cycles, where Z₂ is greater than Z₁. In some embodiments, N₁ and/or N₂ may be several hundred or several thousand cycles. As a result of the repeated contacts between tip surfaces 161 and side surfaces 162 of the wafer-side contact structures 16 against corresponding bottom surfaces 202 and side surfaces 201 of cavities 203 of the shaping wafer 200, the tip/side surfaces 161/162 can be shaped to approximate the shape of the cavities 203. In at least some embodiments, such shaping of the tips/sides 161/162 may bring the wafer-side contact structures 16 back to their within-specification dimension, i.e., make the wafer-side contact structures 16 suitable for testing semiconductor dies on a production wafer. In some embodiments, the shaping of the wafer-side contact structures 16 may include abrasion of the tip/side surfaces 161/162 or plastic deformation of the contact structures 16. The repetitive contacts between the wafer-side contact structures 16 and the shaping wafer 200 may be termed coining or forging of the contact structures 16.

In some embodiments, the shaping wafer 200 can be made of silicon or metals. The cavities 203 may be made by, for example, lithographically defined etching. Since the location precision is defined by the precision of a lithographic mask over the shaping wafer 200, the resulting location precision of the cavities 203 is also relatively high. In at least some embodiments, the precision of the location of the cavities 203 (e.g., tolerances) generally corresponds to the precision of the location of the die contacts 26. In some embodiments, a pitch P₃ between the neighboring wafer-side contact structures 16 corresponds to a pitch P₂ between the neighboring cavities 203.

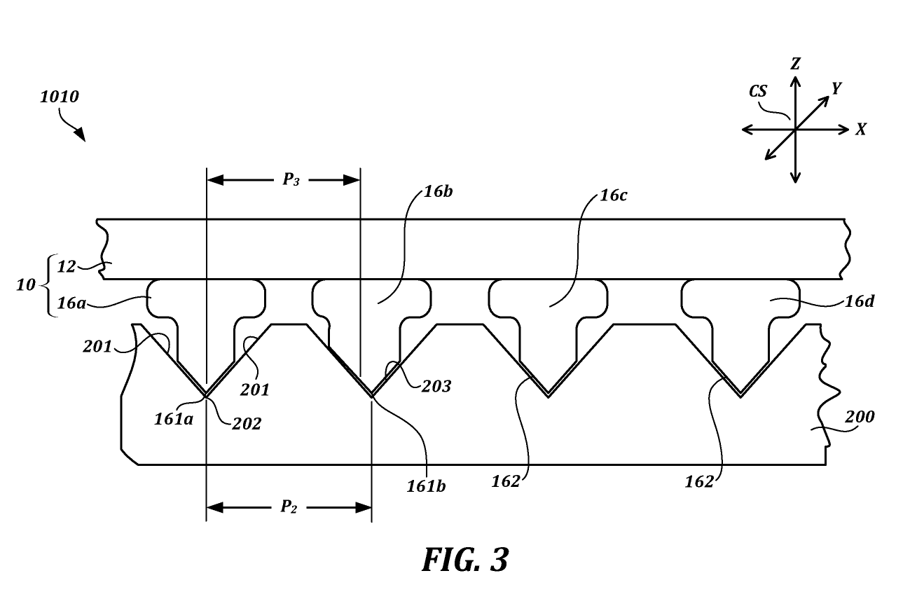

FIG. 3 is a partial side view of a system 1010 for shaping the wafer-side contact structures 16 in accordance with an embodiment of the presently disclosed technology. The system 1010 includes the wafer translator 10 and the shaping wafer 200. The wafer translator 10 may include the wafer-side contact structures 16 having different sizes, shapes and/or pitches. For example, the wafer-side contact structures 16a and 16b may be spaced apart by an out-of-specification distance (pitch) P₃ (e.g., a distance from a centerline of the wafer-side contact structure 16a to a centerline of the wafer-side contact structure 16b). In some embodiments, the wafer-side contact structures 16a and 16b face the bottom surfaces 202 of the cavities in the shaping wafer 200 that are spaced apart by within-specification value P₂. As the bottom surfaces 202 and the side surfaces 201 repeatedly contact the wafer-side contact structures 16a and 16b, the tip surfaces 161a and 161b are shaped to the within-specification pitch P₂. In at least some embodiments, such shaping may be adequate for properly contacting the die contacts 26 even though the tip surface 161b does not coincide with a centerline of the wafer-side contact structure 16b.

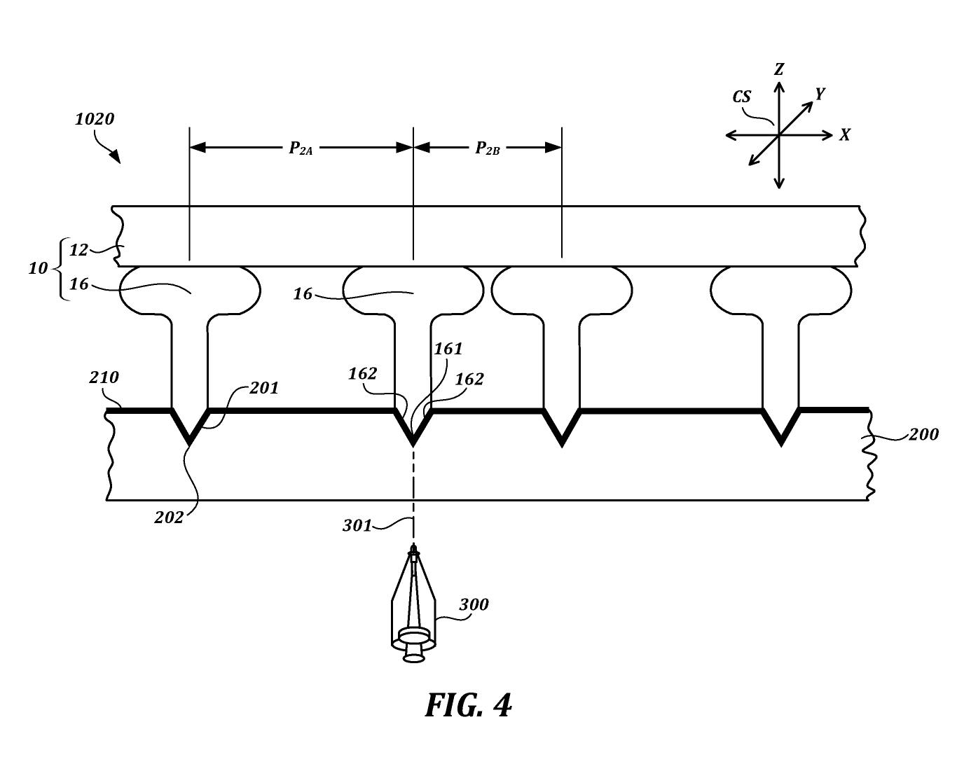

FIG. 4 is a partial side view of a system 1020 for shaping the wafer-side contact structures 16 in accordance with an embodiment of the presently disclosed technology. The system 1020 may include the wafer translator 10, the shaping wafer 200, and an energy source 300. In some embodiments, the shaping of the wafer-side contact structures 16 can include heating the tip surfaces 161 and/or the side surfaces 162 with a beam 301 to soften or melt the material of the wafer-side contact structures 16. Since the volume of the wafer-side contact structures 16 that softens/melts can be relatively small, the required energy for the softening/melting can also be small. As a result, a thermal expansion of the targeted wafer-side contact structures 16 can also be small. In some embodiments, the energy source 300 may be a laser or an LED emitting light at the wavelengths that is transmitted through the shaping wafer 200 made of silicon. In some embodiments, the energy source 300 may emit light in the infrared spectrum. In at least some embodiments, when the wafer-side contact structures 16 are partially softened/melted, the stresses caused by the shaping of the wafer-side contact structures 16 are reduced, which protects the structures of the wafer translator substrate 12.

In some embodiments, one or more coating layers 210 may be configured over the shaping wafer 200. The coating layer 210 may include metals for alloying with the material of the wafer-side contact structures 16, for improving oxidation resistance, and/or for increasing surface hardness of the wafer-side contact structures 16. Some examples of the coating layers are palladium or gold to prevent oxidation, or solder flux to remove oxidation on the wafer-side contact structures 16. In some embodiments, one of the coating layers 210 may include hard ceramics or thermal oxide to reduce adhesion between the wafer-side contact structures 16 and the shaping wafer 200. Multiple coating layers 210 may be used, for example to achieve different desired effects on the wafer-side contact structures 16 (e.g., hardness, low adhesion, etc.).

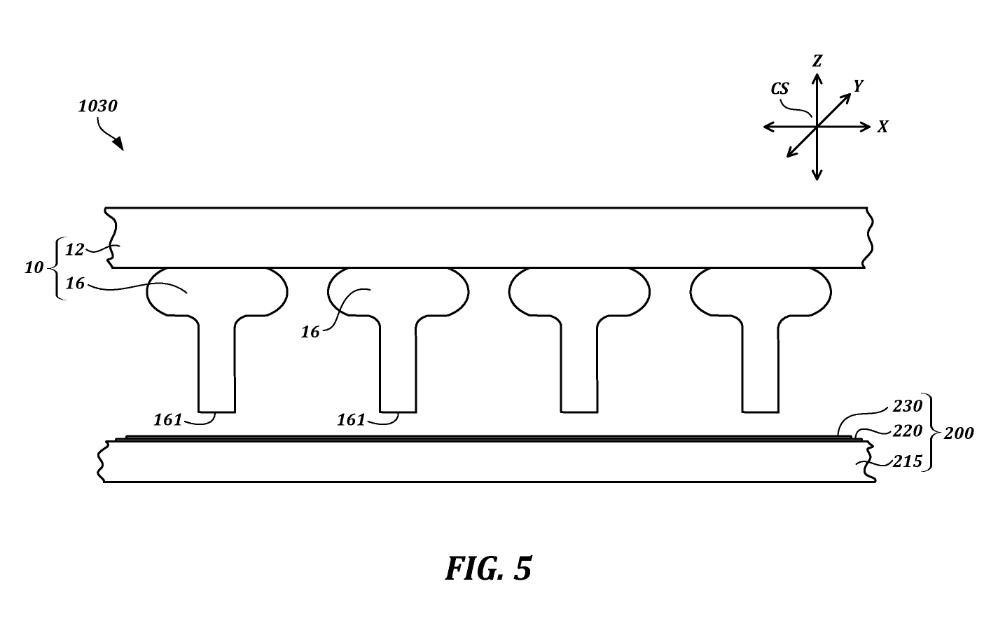

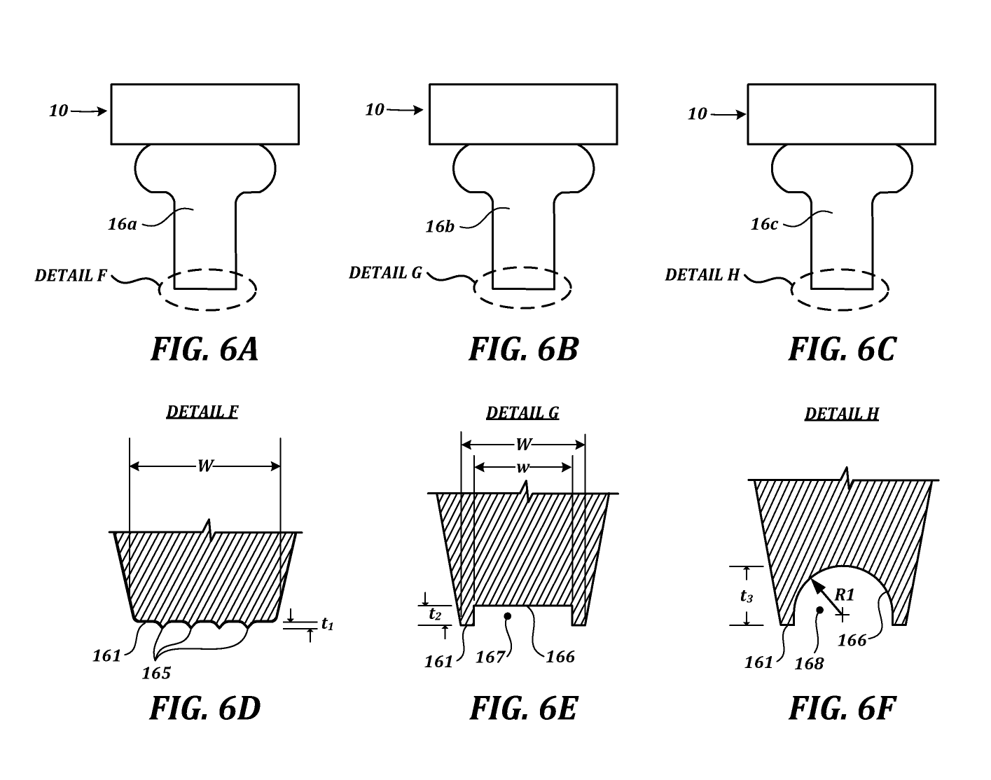

FIG. 5 is a partial side view of a system 1030 for shaping the wafer-side contact structures 16 in accordance with an embodiment of the presently disclosed technology. The system 1030 includes the wafer translator 10 and the shaping wafer 200. In some embodiments, the shaping wafer 200 includes a substrate 215, an adhesion layer 220 and a texturing layer 230. The tip surfaces 161 of the wafer-side contact structures 16 may repeatedly contact the texturing layer 230, for example by moving the shaping wafer 200 or the wafer translator 10 in the Z direction. The texturing layer 230 includes micro shapes that impart specific roughness pattern (i.e., the micro shapes) onto the tip surfaces 161. Because of the relatively small size of the micro shapes, the force between the wafer translator 10 and the shaping wafer 200 may also be relatively small, therefore limiting stress on the wafer-side contact structures 16 and the wafer translator substrate 12. In some embodiments, the system may include the coating layers 210 and/or softening/melting of the wafer-side contact structures 16 described with reference to FIG. 4. Some embodiments of the micro shapes are described in more details with reference to FIGS. 6A-6F below.

FIGS. 6A-6F are partial side views of the wafer-side contact structures 16 in accordance with the embodiments of the presently disclosed technology. FIG. 6D is a cross-sectional detail F of the contact structure 16 shown in FIG. 6A. With an appropriate shape of the texturing layer 230 (e.g., the microprotrusions or microcavities), the repeated contact between the shaping wafer 200 and the texturing layer 230 can result in microtips 165 distributed over a width W of the tip surface 161. In some embodiments, the microtips 165 generally correspond to microcavities (not shown) in the texturing layer 230. A relatively small height t₁ of the microtips 165 may help breaking through the oxides on the die contacts 26, while preventing or limiting damage to the layers underneath the die contacts 26 (e.g., limiting damage to intermediate layer dielectric or ILD). In some embodiments, the height t₁ may be at the μm scale, for example 10-100 μm.

FIG. 6E is a cross-sectional detail G of the contact structure 16 shown in FIG. 6B. FIG. 6E illustrates a depression surface 166 made by the repeated contact between the shaping wafer 200 and the microshapes of the texturing layer 230. A cavity 167 has a width w and a height t₂ from the tip surface 161. In some embodiments, a contact between a wafer-side contact structure 16 and a die contact 26 may be improved, for example when the die contact 26 includes roughness or uneven structure that at least partially fits within the cavity 167.

FIG. 6F is a cross-sectional detail H of the contact structure 16 shown in FIG. 6C. FIG. 6F illustrates a cavity 168 in the contact structure 16. The cavity 168 may be spherical or circular with a radius R and a height t₃.

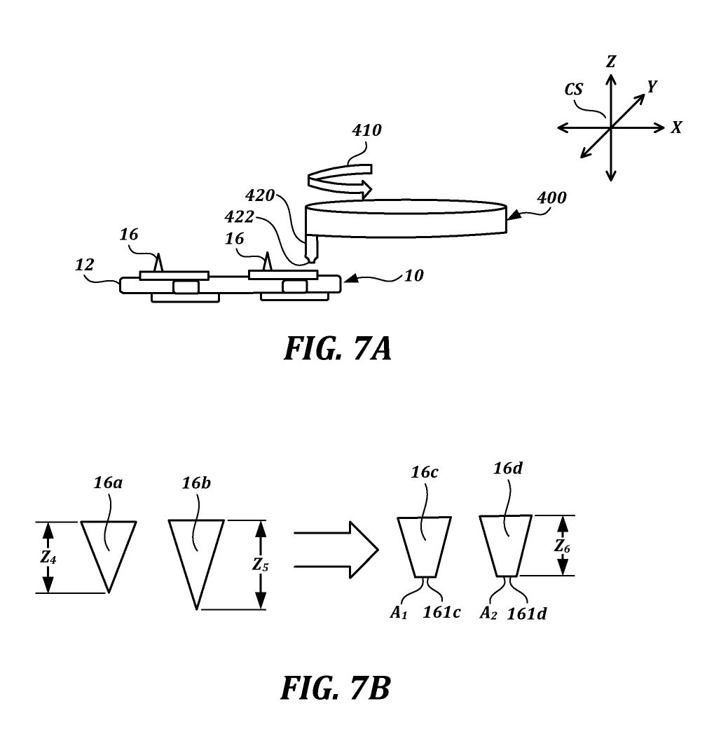

FIGS. 7A and 7B are partially schematic views of a system for shaping the wafer-side contact structures in accordance with the embodiments of the presently disclosed technology. In some embodiments, height of the wafer-side contact structures 16 can be made more uniform by fly-cutting. For example, a rotating tool 400 may carry a cutting tool 420 having a tool tip 422 for the fly-cutting. In some embodiments, a rotation 410 of the tool tip 422 shortens the wafer-side contact structures 16 down to a more uniform height. For example, the wafer-side contact structures 16a and 16b having heights Z₄ and Z₅, respectively, may be shortened to a uniform height Z₆. In at least some embodiments, the resulting non-uniformity of the surface areas A₁ and A₂ of the tip surfaces 161c and 161d may be preferred over the non-uniformity of the heights Z₄ and Z₅. In some embodiments, the tool tip 422 can be a diamond tip. In some embodiments, the tool 400 may traverse over the wafer translator 10 at a feed rate of about 0.01-0.1 mm/sec. In some embodiments, the tool 400 may make several passes, for example, by increasing the cutting depth in 0.5-2 μm increments. In some embodiments, the resulting height variation of Z₆ may be within 0.25 μm over the area of a given die on the wafer. In some embodiments, the systems and methods described with reference to FIGS. 7A and 7B may be used in conjunction with the systems and methods described with reference to FIGS. 2-6F. For example, the coining/forging of the wafer-side contacts 16 may follow the fly cutting.

From the foregoing, it will be appreciated that specific embodiments of the technology have been described herein for purposes of illustration, but that various modifications may be made without deviating from the disclosure. For example, in some embodiments, the wafer-side contact structures 16 may be made of metal alloys. In some embodiments, the wafer-side contact structures 16 may be made from wirebonds using the wirebonding equipment. Moreover, while various advantages and features associated with certain embodiments have been described above in the context of those embodiments, other embodiments may also exhibit such advantages and/or features, and not all embodiments need necessarily exhibit such advantages and/or features to fall within the scope of the technology. Accordingly, the disclosure can encompass other embodiments not expressly shown or described herein.

The embodiments of the invention in which an exclusive property or privilege is claimed are defined as follows:

1. An apparatus for adjusting a wafer translator for testing semiconductor dies, comprising:
the semiconductor wafer translator comprising:
a wafer translator substrate having a wafer-side configured to face the dies, and an inquiry-side facing away from the wafer-side, and
a plurality of wafer-side contact structures carried by the wafer-side of the wafer translator; and
a shaping wafer comprising:
a shaping wafer substrate, and
a plurality of cavities in the shaping wafer substrate, wherein individual cavities face individual wafer-side contact structures, and wherein the wafer-side contact structures are shaped by contacting surfaces of the cavities of the shaping wafer substrate.

2. The apparatus of claim 1, further comprising inquiry-side contact structures, wherein the wafer-side contact structures have a first scale, wherein the inquiry-side contact structures have a second scale, and wherein the first scale is smaller than the second scale.

3. The apparatus of claim 1, wherein the cavities of the shaping wafer are arranged in a first pitch, wherein the wafer-side contact structures are arranged in a second pitch, and wherein the first pitch and the second pitch are the same.

4. The apparatus of claim 1, wherein the wafer-side contact structures are wirebonds or stud-bumps.

5. The apparatus of claim 1, wherein the wafer-side contact structures are shaped by abrasion.

6. The apparatus of claim 1, wherein the wafer-side contact structures are shaped by plastic deformation.

7. The apparatus of claim 6, further comprising a texturing layer over the shaping wafer substrate, wherein the texturing layer faces the wafer-side contact structures of the wafer translator.

8. The apparatus of claim 6, wherein the texturing layer includes microshapes selected from a group consisting of microprotrusions, microcavities, or a combination thereof.

9. The apparatus of claim 1, wherein the shaping wafer comprises silicon, the apparatus further comprising a source of light configured to direct a beam of light to at least one wafer-side contact structure, wherein the beam of light at least partially softens or melts the at least one wafer-side contact structure.

10. The apparatus of claim 1, wherein the shaping wafer includes a coating layer configured to contact the wafer-side contact structure, and wherein the coating layer comprises at least one metal for alloying with the material of the wafer-side contact structures.

11. A shaping wafer, comprising:
a shaping wafer substrate, and
a plurality of cavities in the shaping wafer substrate, wherein individual cavities face individual wafer-side contact structures of a wafer translator, and wherein surfaces of the cavities of the shaping wafer are configured to shape the wafer-side contact structures by contacting the wafer-side contact structures.

12. The shaping wafer of claim 11, wherein the shaping wafer substrate comprises silicon.

13. The shaping wafer of claim 12, wherein the shaping wafer comprises a source of light configured to direct a beam of light to at least one wafer-side contact structure, wherein the beam of light at least partially softens or melts the at least one wafer-side contact structure.

14. The shaping wafer of claim 11, wherein the semiconductor wafer translator has inquiry-side contact structures opposite the wafer-side contact structures, wherein the wafer-side contact structures have a first scale, wherein the inquiry-side contact structures have a second scale, and wherein the first scale is smaller than the second scale.

15. The shaping wafer of claim 11, further comprising a texturing layer over the shaping wafer substrate, wherein the texturing layer faces the wafer-side contact structures of the wafer translator.

16. The shaping wafer of claim 15, wherein the texturing layer includes microshapes selected from a group consisting of microprotrusions, microcavities, or a combination thereof.

17. The shaping wafer of claim 11, wherein the shaping wafer includes a coating layer configured to contact the wafer-side contact structure, and wherein the coating layer comprises at least one metal for alloying with the material of the wafer-side contact structures.

18. An apparatus for adjusting a wafer translator for testing semiconductor dies, comprising:
a semiconductor wafer translator comprising:
a wafer translator substrate having a wafer-side configured to face the dies, and an inquiry-side facing away from the wafer-side, and
a plurality of wafer-side contact structures carried by the wafer-side of the wafer translator; and
a rotating tool configured to shorten the wafer-side contact structures by a fly-cutting.

19. The apparatus of claim 18, wherein the rotating tool comprises a cutting tool.

20. The apparatus of claim 18, wherein a variation in height of the wafer-side contact structures is within 25 μm after the fly-cutting.

21. The apparatus of claim 18, wherein the wafer-side contact structures are wirebonds or stud-bumps.

22. A method for adjusting a wafer translator for testing semiconductor dies, comprising:
aligning the wafer translator and a shaping wafer, wherein wafer-side contact structures at a wafer-side of the wafer translator face cavities of the shaping wafer;
repeatedly contacting the wafer-side contact structures by surfaces of the cavities of the shaping wafer;
shaping the wafer-side contact structures into a within-specification value by abrasion or forging.

23. The method of claim 22, further comprising generating depression surfaces on tip surfaces of the wafer-side contact structures.

24. The method of claim 22, further comprising generating microtips on tip surfaces of the wafer-side contact structures.

25. The method of claim 22, further comprising applying a force from a pressure driven actuator for repeatedly contacting the wafer-side contact structures.

26. The method of claim 22, further comprising:
moving the wafer translator into a position Z₁ for N₁ cycles; and
moving the wafer translator into a position Z₂ for N₂ cycles, wherein Z₂ is greater than Z₁.

27. The method of claim 22, wherein the shaping wafer includes a coating layer, the method further comprising alloying the wafer-side contact structures with materials of the coating layer.

28. The method of claim 22, further comprising heating the wafer-side contact structures with a beam emitted by an energy source.

29. The method of claim 22, wherein the wafer-side of the wafer translator carries contact structures having a first scale, and the inquiry-side of the wafer translator carries the contact structures having a second scale, wherein the first scale is smaller than the second scale.

30. The method of claim 22, further comprising testing the semiconductor dies.

31. The method of claim 22, further comprising:
attaching a segment of singulated wafer translator to a die by intermetallic bonds, wherein the wafer-side of the segment faces die contacts of the die, and wherein the wafer-side contact structures are wirebonds or stud bumps.
